(19) United States
(12) Patent Application Publication
(10) Pub. No.: US 2006/0014323 A1
(43) Pub. Date: Jan. 19, 2006

(54) Thermal interface material with fluid

(75) Inventors: Yang-Chang Chien, Tu-Cheng (TW); Yuan-Heng Huang, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/168,807

(22) Filed: Jun. 28, 2005

(30) Foreign Application Priority Data
Jul. 2, 2004 (CN) 200410027981.5

(51) Int. Cl. H01L 21/44

(52) U.S. Cl. 438/122

(57) ABSTRACT

A thermal interface material is provided to insert into a gap (49) between a heat sink (20) and a heat source (30) in order to dissipate heat from the heat source. The gap has air (51) therein. The thermal interface material may include a fluid (11) and a number of metal particles (12) in the fluid. The metal particles may react with the air to form one or metal compounds (13) at least partly filling the gap.

### FIELD OF THE INVENTION

The present invention relates to thermal interface materials, such as a thermal interface material positioned between a heat sink and a heat source.

### BACKGROUND OF THE INVENTION

Nowadays semiconductor devices are smaller and run faster than ever before. These devices also generate more heat than ever before. A semiconductor device should be kept within its operational temperature limits to ensure good performance and reliability. Referring to FIG. 3, to keep a semiconductor device 70 in its operational temperature range, a heat sink 60 is attached to a surface of the semiconductor device 70. Heat is transferred from the semiconductor device 70 to ambient air via the heat sink 60. When the heat sink 60 is attached to the semiconductor device 70, their surfaces are adjacent to each other. However, as much as 99% of the surfaces are actually separated by a small layer of interstitial air 90, no matter how precisely the heat sink 60 and semiconductor device 70 are manufactured.

Referring to FIG. 4, a thermal interface material 50 can be positioned in a region of interstitial air between a heat sink 62 and a semiconductor device 72. The thermal interface material 50 is mobile over the semiconductor device 72, thereby filling the space between the heat sink 62 and the semiconductor device 72. However, the viscosity of the thermal interface material 50 limits its spreadability, so that the space 92 between the heat sink 62 and the semiconductor device 72 cannot be fully filled. Thus air remains in unfilled portions of the space 92, which increases the thermal resistance between the heat sink 62 and the semiconductor device 72.

Thus, an interface material which overcomes the above-mentioned problems is desired.

### SUMMARY

Accordingly, an object of the present invention is to provide an interface material filling a gap between a heat sink and a heat source for facilitating heat transfer from the heat source.

To achieve the above-mentioned object, a thermal interface material is provided to insert into a gap between a heat sink and a heat source in order to dissipate heat from the heat source. The gap has air therein. The thermal interface material may include a fluid and a number of metal particles in the fluid. The metal particles may react with the air to form one or metal compounds at least partly filling the gap. The reaction reduces the amount of air between the heat sink and the heat source, thereby decreasing the thermal resistance between the heat sink and the heat source.

Preferably, the metal particles are made of a metallic material selected from the group consisting of aluminum, magnesium, and iron. The metal compounds may be metal oxides. The metal compounds may be metal nitrides.

The metal oxides and metal nitrides may be provided to replace the amount of air between the heat sink and the heat source. Because the metal oxides and metal nitrides conduct heat better than the amount of air, the efficiency of the thermal conduction between the heat sink and the heat source is increased by this replacement.

Other advantages and novel features will be drawn from the following detailed description of preferred embodiments together with the attached drawings, in which:

### BRIEF DESCRIPTION OF THE DRAWINGS

FIG. 1 is a schematic view of a heat dissipating assembly, showing a thermal interface material of the present invention positioned between a heat sink and a heat source before the interface material reacts with air;

FIG. 2 is similar to FIG 1, but showing the assembly after the interface material has reacted with air;

FIG. 3 is a schematic view of a conventional assembly including a heat sink and a semiconductor device; and

FIG. 4 is similar to FIG. 3, but showing a conventional thermal interface material positioned between a heat sink and a semiconductor device.

### DETAILED DESCRIPTION OF PREFERRED EMBODIMENTS

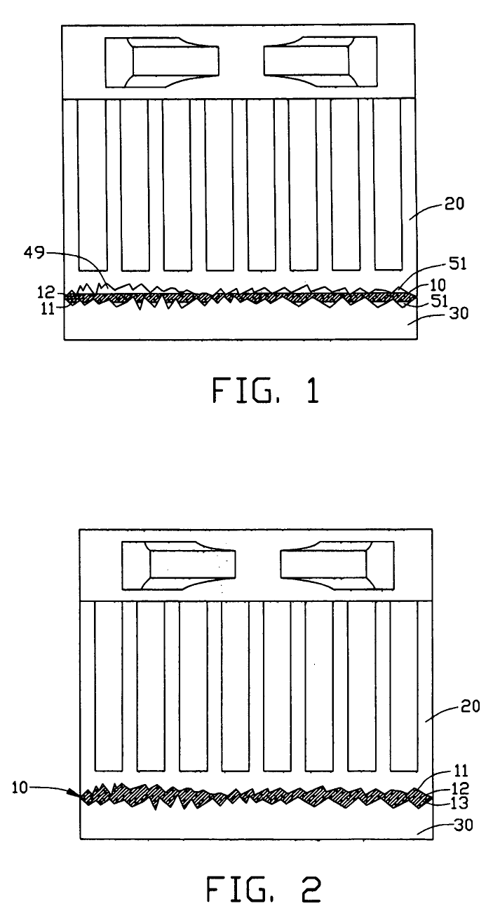

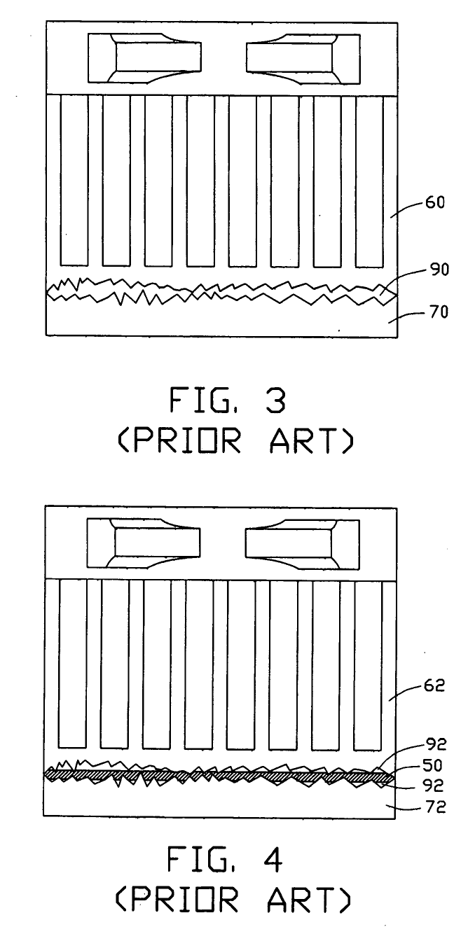

In one aspect, the present invention provides a thermal interface material for filling a gap between two thermal objects, of which a first thermal object is exemplarily a heat sink and a second thermal object is exemplarily a heat source, and thereby facilitating transfer of heat from the heat source to the heat sink. Referring to FIGS. 1 and 2, the heat source 30 and the heat sink 20 are partially separated by a gap 49 having air 51 therein. The thermal interface material 10 includes a fluid 12, and a number of metal particles 11 distributed in the fluid 12. The metal particles 11 react with the air 51 to form one or more metal compounds 13, whereby the thermal interface material 10 substantially fully fills the gap 49 between the heat sink 20 and the heat source 30.

The metal particles 11 are made of a metallic material that can readily chemically react with the air 51. Such metallic material may be aluminum, magnesium, iron, or any combination thereof. Each of the metal particles 11 may have a diameter in the range from about 1 to about 100 nanometers. The metal particles 11 are added into the fluid 12, and subsequently react with the air 51 to form the metal compounds 13 that fills up the gap 49 between the heat sink 20 and the heat source 30. The metal compounds 13 include metal oxides and metal nitrides. The fluid 12 is selected from the group consisting of oil, grease, and a colloid. The oil is preferably mineral oil, silicon oil, petroleum jelly, or Vaseline™. The grease is preferably animal grease or plant grease. The colloid is preferably silica gel, polyethylene glycol, epoxy resin or an acrylic.

Referring back to FIG. 1, the thermal interface material 10 is positioned between the heat source 30 (e.g., a CPU—central processing unit) and the heat sink 20. The fluid 12 of the thermal interface material 10 is mobile, thereby filling the gap 49 between the heat sink 20 and the heat source 30. Even if the fluid 12 cannot fully fill the gap 49, the metal particles 11 in the fluid 12 are chemically reactive enough to react with the air 51 between the heat sink 20 and the heat source 30. The product of the reaction is the metal compounds 13 (see FIG. 2), which reduce or eliminate the air 51 between the heat sink 20 and the heat source 30.

Referring to FIG. 2, the metal compounds 13 and the fluid 12 may substantially fill up the space between the heat sink 20 and the heat source 30. That is, the thermal interface material 10 closely attaches the heat sink 20 to the heat source 30, thereby providing intimate thermal contact between the heat sink 20 to the heat source 30.

The previously described aspects of the present invention have many advantages. First, the metal particles are chemically reactive enough to react with the air. Approximately eighty percent of air is nitrogen, and approximately twenty percent of air is oxygen. The nitrogen reacts with the metal particles to form metal nitrides. The oxygen reacts with the metal particles to form metal oxides. These reactions reduce the amount of air between the heat sink and the heat source, thereby decreasing the thermal resistance between the heat sink and the heat source. From another point of view, the metal oxides and metal nitrides are formed to replace the amount of air between the heat sink and the heat source. Because the metal oxides and metal nitrides conduct heat better than the amount of air, the efficiency of the thermal conduction between the heat sink and the heat source is increased by this replacement.

Second, each of the metal particles preferably has a diameter in the range from about 1 to about 100 nanometers. Therefore the metal particles have a large surface area. This large surface area increases the reaction rates, thereby effectively reducing or eliminating the air between the heat sink and the heat source. This increases the efficacy of the thermal interface material.

It is understood that the above-described embodiments are intended to illustrate rather than limit the invention. Variations may be made to the embodiments without departing from the spirit of the invention. Accordingly, it is appropriate that the appended claims be construed broadly and in a manner consistent with the scope of the invention.

What is claimed is:

1. A thermal interface material comprising:
a fluid; and
a plurality of metal particles in the fluid, the metal particles being reactive with air.

2. The thermal interface material as described in claim 1, wherein the metal particles are made of a metallic material selected from the group consisting of aluminum, magnesium, and iron.

3. The thermal interface material as described in claim 2, wherein the metal particles react with the air to form metal compounds comprising metal oxides.

4. The thermal interface material as described in claim 2, wherein the metal particles react with the air to form metal compounds comprising metal nitrides.

5. The thermal interface material as described in claim 1, wherein each of the metal particles has a diameter in the range from about 1 to about 100 nanometers.

6. The thermal interface material as described in claim 1, wherein the fluid is selected from the group consisting of oil, grease, and a colloid.

7. The thermal interface material as described in claim 6, wherein the oil is selected from the group consisting of mineral oil, silicon oil, petroleum jelly, and Vaseline™.

8. The thermal interface material as described in claim 6, wherein the grease is animal grease or plant grease.

9. A heat dissipating assembly comprising:
a heat sink;
a heat source; and
a thermal interface material positioned between the heat sink and the heat source, wherein the thermal interface material comprises a fluid and a plurality of metal particles distributed therein, and the metal particles are reactive with air between the heat sink and the heat source, whereby the thermal interface material closely contacts the heat sink and the heat source.

10. A method to attach a first thermal object to a second thermal object for heat transmission therebetween, comprising the steps of:
preparing a thermal interface material having a plurality of air-reactive metal particles;
placing said thermal interface material between said first and second thermal objects; and
expelling air between said first and second thermal objects by having said plurality of metal particles reacting with said air so as to enhance said heat transmission between said first and second thermal objects.

11. The method as described in claim 10, wherein said plurality of metal particles is distributed in a fluid of said thermal interface material.
